(19) United States
(12) Patent Application Publication
(10) Pub. No.: US 2008/0297206 A1
(43) Pub. Date: Dec. 4, 2008

(54) Dc Offset Estimation

(75) Inventor: Adrian Weston Payne, Redhill (GB)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics, N.V., Eindhoven (NL)

(21) Appl. No.: 12/093,991

(22) PCT Filed: Nov. 15, 2006
(86) PCT No.: PCT/IB2006/054268

§ 371 Date: May 16, 2008

(30) Foreign Application Priority Data
Nov. 18, 2005 (EP) 05110952.8

(51) Int. Cl. H03D 3/00

(52) U.S. Cl. 327/104

(57) ABSTRACT

A Bluetooth® enhanced data rate receiver (1) has a DC offset estimation circuit (9) comprising a detector (10) for identifying turning points in a demodulated signal and measuring the signal level at these turning points. The detector (10) discards measured levels of maxima that are not sufficiently different to a level of a preceding minimum and levels of minima that are not sufficiently different to a level of a preceding maximum. The detector (10) also discards levels that are smaller than certain thresholds. An averaging means (11) calculates the average of each adjacent maximum and minimum levels of the signal output by the detector (10). A processing means (12) selects a high, low and medium value of the calculated averages and estimates a DC offset value as the average of this set of calculated averages.

### FIELD OF THE INVENTION

This invention relates to a DC offset estimation circuit and to a method of DC offset estimation. A particular, but not exclusive, application of the invention is estimation of DC offset in Bluetooth®.

### BACKGROUND OF THE INVENTION

In wireless communications, there is often a difference between a carrier frequency with which a signal is transmitted over the communication system and a so-called local oscillator frequency with which a receiver tries to receive the signal. When the signal is demodulated using a non-coherent demodulator, this can lead to the demodulated signal containing an unwanted component representing the difference between the carrier frequency and the local oscillator frequency, which unwanted component is known as a DC (Direct Current) offset.

Virtually all wireless communication receivers incorporate means for trying to eliminate DC offset from their demodulated signal. This means might be a DC offset correction circuit that subtracts an estimate of the DC offset from the demodulated signal or an Automatic Frequency Control (AFC) system that adjusts the local oscillator frequency toward the carrier frequency. In either case, the first step is usually to estimate the DC offset of the demodulated signal.

In one example, the DC offset correction circuit of a Bluetooth® receiver uses a so-called “MaxMin” technique for estimating DC offset. In more detail, the maximum level of the signal and the minimum level of the signal are detected and stored by the DC offset correction circuit. The circuit is arranged such that the stored levels decrease or “leak away” towards an intermediate value with a given time constant, but are reset to the maximum or minimum level of the signal whenever greater levels than the stored levels (in terms of deviation from the intermediate value) are detected. From time to time, the average of the stored maximum and minimum levels is calculated and used as a DC offset value. The signal is then corrected by subtracting this DC offset value from the signal.

Such DC offset estimation suffers from a number of problems. For example, in a Bluetooth® receiver, when no signal is actually received, the DC offset correction circuit tends to receive a large random input that causes the detected maximum and minimum levels to be very high. As a signal starts to be received, these levels leak away and are replaced by (lower) levels detected from the received signal, so that the estimated DC offset value can approach the actual DC offset of the received signal. Each data packet starts with a preamble of 4 bits followed by a sync word of 64 bits, which together form part of a so-called access code. The sync word must be correctly received to ensure that the payload of the data packet is correctly received. So, the DC offset needs to be accurately estimated during the preamble. In order to achieve this, the levels must be arranged to leak away quickly. However, this means that the estimated DC offset value can also fluctuate quickly. This fluctuation amounts to noise in the estimated DC offset value, which can lead to the sync word or other subsequent data being incorrectly received. So, the speed with which the maximum and minimum levels are arranged to leak away is inevitably a compromise between these conflicting requirements.

Furthermore, the detected maximum and minimum levels of the signal can be strongly affected by noise in the received signal. As the detected maximum and minimum levels are used directly in the estimation of the DC offset value, the DC offset value may therefore be very inaccurate in the presence of noise. The DC offset value is also strongly affected by the signal content. For example, when a Bluetooth® signal, which is normally modulated by a scheme known as Gaussian Frequency Shift Keying (GFSK), contains a string of binary ones, e.g. 11111, it tends to contain a series of large maximum levels and small minimum levels (in terms of deviation from an intermediate value). This tends to cause the maximum level stored by the DC offset correction circuit to become large, but for the minimum level to leak to a small level. So, the calculated DC offset value tends to increase, even though the actual DC offset might not change.

### SUMMARY OF THE INVENTION

The present invention seeks to overcome these problems.

According to a first aspect of the present invention, there is provided a DC offset estimation circuit comprising:

a detector for repetitively detecting a maximum level and minimum level of a signal;

averaging means for repetitively calculating an average of the detected maximum level and minimum level; and

processing means for selecting a set of the calculated averages and estimating a DC offset value based on the selected set of calculated averages.

Similarly, according to a second aspect of the present invention, there is provided a method of DC offset correction comprising:

detecting a maximum level and minimum level of a signal;

calculating an average of the detected maximum level and minimum level;

repeating the detection and calculation to provide plural averages;

selecting a set of the plural calculated averages; and

estimating a DC offset value based on the selected set of averages.

So, whilst the prior art effectively just assumes the DC offset value to be the average of a detected maximum level and minimum level, the invention allows the DC offset value to be based on a selected set of calculated averages of detected maximum and minimum levels of the signal. This greatly improves the accuracy of the estimated DC offset value.

Estimation of the DC offset value can be based on the selected set of calculated averages in a number of ways. However, it is typically estimated as an average of the selected set of calculated averages. So, it is important to carefully select the set of calculated averages to obtain an accurate DC offset value. This might involve discriminating amongst the calculated averages according to expected dimensions of the signal, such as typical DC offset or expected amplitude for example. In a particularly preferred example, selection of the set of calculated averages can include selecting averages in given ranges of values. Typically, the selection includes selecting an average in a high range of values, and average in a low range of values and an average in a medium range of values.

Whilst the invention involves a certain amount of processing in order to arrive at a DC offset value, it can be quick as it only requires a few detected levels to arrive at an accurate DC offset. However, in order to maximise speed, it is useful to detect substantially every maximum level and every minimum level of at least a portion of the signal on which the DC offset correction is based. So, the detector may determine turning points of the signal, e.g. by looking at the rate of change of the signal, and detect the signal level at each turning point. The detected maximum and minimum levels may then be levels of the turning points of the signal, e.g. levels of the maxima and minima of the signal.

Nonetheless, in order to reduce the effects of noise, it can be useful to discard some detected levels. For example, it can be useful to discard a maximum level of the signal that is less than a given margin different to a preceding minimum level of the signal. Similarly, it can be useful to discard a minimum level of the signal that is less than a/the given margin different to a preceding maximum level of the signal. This can prevent maximum and minimum levels that are too close to one another from being used in the estimation of the DC offset value and improve performance in the presence of noise.

It can also be useful to discard maximum levels and minimum levels of the signal that are smaller than respective first and second thresholds (with respect to an intermediate value). This can again improve performance in the presence of noise. The first and second thresholds could be set at predetermined values. However, it can be useful to vary the thresholds as the signal or, more specifically, the detected maximum and minimum levels change. In particular, the first and second thresholds may be calculated by subtracting a second margin from a mean of the detected maximum levels (before discard) and a mean of the detected minimum levels (before discard) respectively. The second margin can be calculated by scaling a difference between the mean of the detected maximum levels and the mean of the detected minimum levels. This results in the second margin being larger when the difference between the detected maximum and minimum levels becomes larger, e.g. before receipt of a data packet of a Bluetooth® signal, and smaller when the difference between the detected maximum and minimum levels becomes smaller, e.g. after the beginning of receipt of a data packet of a Bluetooth® signal. This has a particular advantage of allowing the estimated DC offset value to change quickly at the beginning of receipt of a data packet, e.g. during the preamble of a data packet, but become more stable during receipt of data after receipt of the preamble, e.g. a sync word of a data packet. It can also be useful to constrain the second margin between upper and lower limits. This ensures that the first and second thresholds do not become too small or too large.

DC offset values estimated as described above tend to be very accurate and responsive, but can still be adversely affected by the presence of excessive noise. It is therefore preferred to calculate a mean of several of the detected maximum and minimum levels of the signal (before discard) and estimate the DC offset value based on the calculated mean when the signal contains excessive noise. For example, it may be determined that the signal contains excessive noise when the difference between the average of the selected set of calculated averages in the high range of values and the average of the selected set of calculated averages in the low range of values is greater than a given value. Similarly, it may be determined that the signal contains excessive noise when the calculated mean is higher than the average of the selected set of calculated averages in the high range of values or lower than the average of the selected set of calculated averages in the low range of values. Upon such determination, the calculated mean can be used in the DC offset estimation instead of the set of calculated averages. For example, the set of calculated averages can be replaced by values based on the calculated mean.

It will be appreciated that the invention has wide applicability to a variety of different wireless communication systems. However, it may be particularly useful when the signal is a Frequency Shift Keying (FSK) modulated signal, a Gaussian Minimum Shift Keying (GMSK) modulated signal, a Gaussian Frequency Shift Keying (GFSK) modulated signal or a Binary Phase Shift Keying (BPSK) modulated signal. More specifically, the invention finds particular application when used in a Bluetooth® receiver or for receiving a Bluetooth® signal. It also finds application in a Digital Enhanced Cordless Telecommunications (DECT) receiver or for receiving a DECT signal. Naturally, it also extends to a receiver incorporating the DC offset estimation circuit described above and to a method of receiving a signal incorporating the DC offset estimation method described above.

Use of the terms “detector”, “averaging means”, “processing means”, etc. above is intended to be general rather than specific. The invention may be implemented using such separate components. However, it may equally be implemented using individual processor, such as a digital signal processor (DSP) or central processing unit (CPU). Similarly, the invention could be implemented using a hard-wired circuit or circuits, such as an application-specific integrated circuit (ASIC), or by embedded software. Indeed, it can also be appreciated that the invention can be implemented using computer program code. According to a further aspect of the present invention, there is therefore provided computer software or computer program code adapted to carry out the method described above when processed by a processing means. The computer software or computer program code can be carried by a computer readable medium. The medium may be a physical storage medium such as a Read Only Memory (ROM) chip. Alternatively, it may be a disk such as a Digital Versatile Disk (DVD-ROM) or Compact Disk (CD-ROM). It could also be a signal such as an electronic signal over wires, an optical signal or a radio signal such as to a satellite or the like. The invention also extends to a processor running the software or code, e.g. a computer configured to carry out the method described above.

### BRIEF DESCRIPTION OF THE DRAWINGS

Preferred embodiments of the invention will now be described with reference to the accompanying drawings, in which:

FIG. 1 is a schematic illustration of a Bluetooth® enhanced data rate receiver incorporating a DC offset estimation circuit according to a preferred embodiment of the present invention;

FIG. 2 is a graphical illustration of a signal demodulated from the access code of a simulated Bluetooth® data packet showing various levels detected and calculated by the DC offset estimation circuit illustrated in FIG. 1;

FIG. 3 is a flowchart illustrating operation of the DC offset estimation circuit illustrated in FIG. 1; and

FIG. 4 is a graphical representation of simulated numbers of packet errors at different DC offset values using a DC offset estimation circuit of the prior art and the DC offset estimation circuit illustrated in FIG. 1.

### DETAILED DESCRIPTION OF THE INVENTION

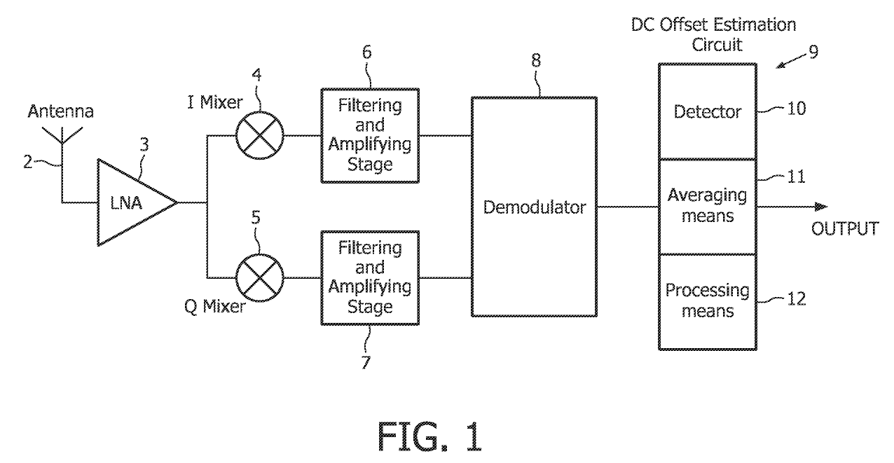

Referring to FIG. 1, a Bluetooth® enhanced data rate receiver 1 has an antenna 2 for receiving a signal. This signal changes between a Gaussian Frequency Shift Keying (GFSK) modulated signal and, during higher data rate periods, either a 7/4 Differential Quadrature Phase Shift Keying (7/4 DQPSK) modulated signal or an Eight-ary Differential Phase Shift Keying (D8PSK) modulated signal. The antenna 2 is connected to a Low Noise Amplifier (LNA) 3 for amplifying the received signal and outputting it to I and Q mixers 4, 5. The I and Q mixers 4, 5 are adapted to extract the I and Q components of the signal at output them to respective filtering and amplifying stages 6, 7. The filtering and amplifying stages 6, 7 filter and amplify the I and Q components of the received signal and output the filtered, amplified I and Q components of the signal to a demodulator 8. The demodulator 8 demodulates the filtered, amplified I and Q components of the signal in accordance with the appropriate modulation scheme and outputs a demodulated signal to a DC offset estimation circuit 9.

The DC offset estimation circuit 9 comprises a detector 10 for detecting maximum and minimum levels of the demodulated signal. More specifically, the detector 10 is adapted to identify turning points in the demodulated signal. A turning point when the rate of change of the signal level turns from positive to negative is a maximum or peak of the signal and a turning point when the rate of change of the signal turns from negative to positive is a minimum or trough of the signal. The detector 10 is able to measure the signal level at these maximums and minimums to detect maximum and minimum levels of the signal. Ideally, the detector 10 could output the measured signal levels at each maximum and minimum as a detected maximum or minimum level, providing a succession of held-max and held-min values replaced with each newly measured level. However, in reality, mainly due to noise, not all maximum and minimums of the signal provide useful maximum and minimum levels. The detector 10 only therefore outputs the measured level of a detected maximum or minimum as new held-max or held-min values when the measured signal level of the detected maximum or minimum meets certain conditions.

Firstly, the detector 10 determines whether the measured signal level of a maximum has a value different to a current held-min value by more than a first margin. If the measured signal level is closer to the current held-min value than the first margin, then the measured signal level is not output as a new held-max value. A new held-max value is only output by the detector 10 if it differs from the current held-min value by more than the first margin. The same applies to the output of new held-min values. More specifically, the detector 10 determines whether the measured signal level of a minimum has a value different to the current held-max value by more than the first margin. If the measured signal level is closer to the current held-max value than the first margin, then the measured signal level is not output as a new held-min value. A new held-min value is only output by the detector 10 if it differs from the current held-max value by more than the first margin. In this embodiment, the first margin is 0.7 radians, which means that the held-max and held-min values always differ from one another by around 20 kHz. Of course, in other embodiments, different first margins can be selected to suit particular applications.

Secondly, the detector 10 determines whether the measured signal level of a maximum is larger than a first threshold. If the measured signal level is smaller than the first threshold, then the measured signal level is not output as a new held-max value. A new held-max value is only output by the detector 10 if it is larger than the first threshold. The same applies to the output of new held-min values. More specifically, the detector 10 determines whether the measured signal level of a minimum is larger than a second threshold. If the measured signal level is smaller than the second threshold, then the measured signal level is not output as a new held-min value. A new held-min value is only output by the detector 10 if it is larger than the second threshold.

The detector 10 determines the first and second thresholds by calculating a mean of the measured signal levels for the detected maxima, called mean-max, and a mean of the measured signal levels for the detected minima, called mean-min. The detector 10 then calculates the difference between mean-max and mean-min, called mean-diff, multiplies mean-diff by a scaling factor, which is 0.55 in this embodiment, and constrains it between lower and upper limits, which are 0.7 radians (equivalent to 111 kHz) and 1.5 radians (equivalent to 239 kHz) respectively in this embodiment, to provide a second margin. The detector 10 then subtracts the second margin from mean-max to give the first threshold and subtracts the second margin from mean-min to give the second threshold.

The detector 10 is connected to output the held-max and held-min values to an averaging means 11 for calculating an average, maxmin-average, of each adjacent held-max and held-min value received from the detector 10. The averaging means 11 is, in turn, connected to output the calculated averages to a processing means 12 for selecting a set of the calculated averages on the basis of which to estimate a DC offset value.

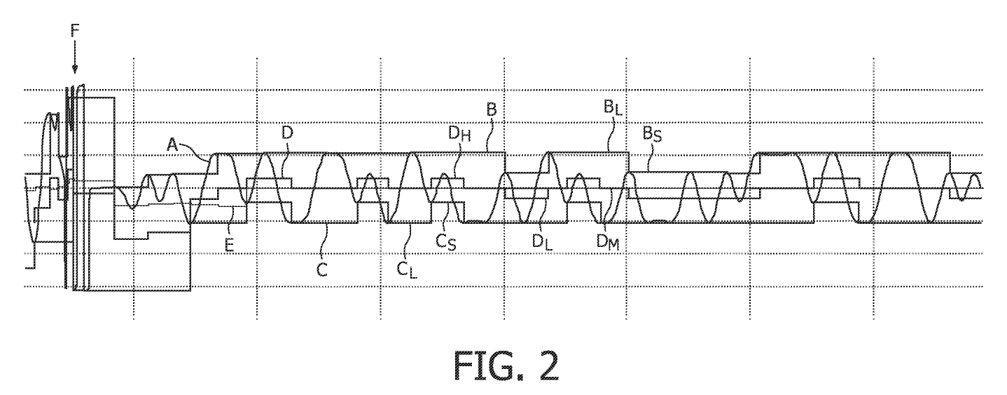

A signal demodulated from the access code of a simulated Bluetooth® data packet is represented in FIG. 2 by line A. It can be appreciated that some maxima and minima are larger than others. Indeed, in a GFSK demodulated signal, maxima and minima in an alternating series of symbols, e.g. 0101, tend to be smaller than maxima and minima in a series of the same symbols, e.g. 0000 or 1111. The detected maximum and minimum levels, held-max and held-min, output by the detector 10 therefore tend to each have two distinct levels. Held-max and held-min are represented in FIG. 2 by lines B and C respectively. It can be seen that the line B representing held-max tends to vary between a large level B_{L} and a small level B_{S}. Similarly, it can be seen that the line C representing held-min tends to vary between a large level C_{L} and a small level C_{S}.

The calculated averages, minmax-average, are averages of different pairs of these large and small levels B_{L}, B_{S}, C_{L}, C_{S}. This means that the calculated averages, minmax-average, tend to have three different values: a high value when held-max is large and held-min is small, e.g. at the end of a sequence of symbols such as 1011, a low value when held-max is small and held-min is large, e.g. at the end of sequence of symbols such as 0100, and a medium value when held-max is large and held-min is large, e.g. at the end of a sequence of symbols such as 0011, or when held-max is small and held-min is small, e.g. at the end of a sequence of symbols such as 0101. The calculated averages, minmax-average, are represented in FIG. 2 by line D, in which a high value minmax-average D_{H}, a low value minmax-average D_{L} and a medium value minmax-average D_{M} can easily be identified.

The processing means 12 is arranged to identify these high, low and medium values of the calculated averages, minmax-average, and then to estimate the DC offset value as the average of this set of calculated averages. The identification is achieved by setting high, low and medium ranges of minmax-average in which the high, low and medium values are expected to lie. These ranges can be based on the mean-max and mean-min levels for example. The processing means 12 identifies values of minmax-average in each of the ranges as the high, low and medium values and estimates the DC offset value as the average of these three values.

This estimated DC offset value is represented by line E in FIG. 2, from which it can be seen that the estimated DC offset level remains relatively constant except at the very beginning of the access code and thus shows reliable DC offset estimation under the simulated conditions. However, there is some fluctuation in the estimated DC offset at the beginning of the access code resulting from the high level of noise seen in section F of the signal. In order to minimise this, the processing means 12 monitors the signal for the presence of excessive noise and estimates the DC offset value differently in the presence of such excessive noise.

More specifically, the processing means 12 calculates the difference between the identified high and low values of the calculated averages and determines that the signal contains excessive noise if this calculated difference is greater than 0.8 radians (equivalent to 127 kHz). Similarly, the processing means 12 calculates a mean of the last few, e.g. around 16, detected maximum and minimum levels of the signal and determines that the signal contains excessive noise if the calculated mean is higher than the high value of the selected set of calculated averages and or lower than the low value of the calculated averages.

The different estimation of the DC offset value, used when the processing means 12 determines that the signal contains excessive noise comprises basing the DC offset estimation on the calculated mean instead of the selected set of calculated averages. More specifically, the processing means replaces the medium value of the calculated averages with the calculated mean and replaces the high and low values of the calculated averages with the calculated mean +0.2 radians and the calculated mean −0.2 radians.

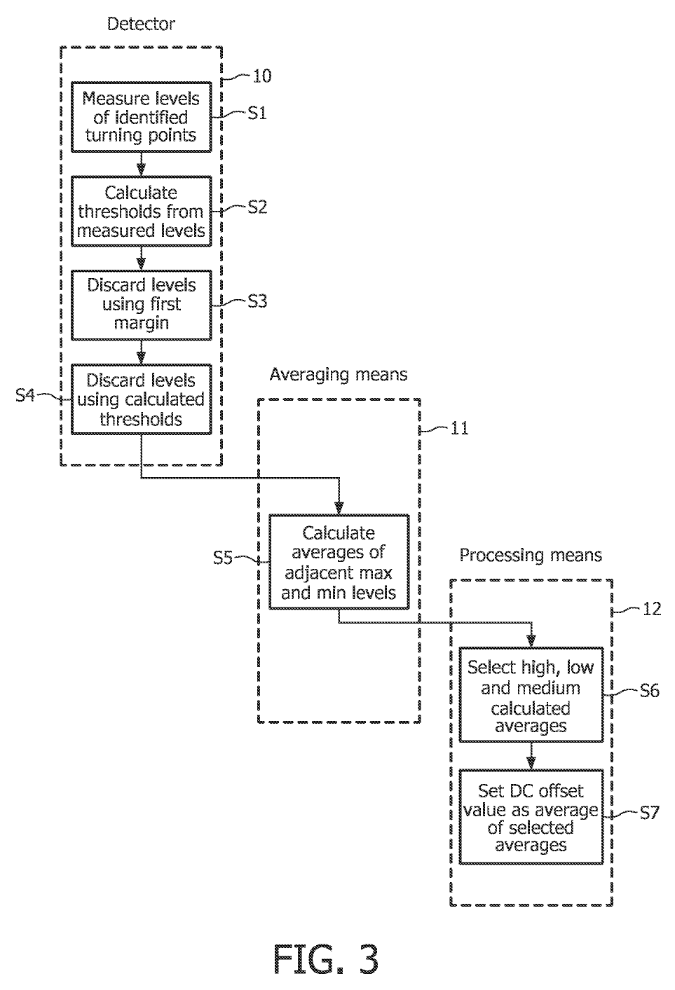

Referring to FIG. 3, in more detail, at step S1, the detector 10 identifies turning points in the demodulated signal and measures the signal level of each turning point. At step S2, the detector 10 calculates first and second thresholds from the measured signal levels of the turning points by calculating a mean level, mean-max, of the measured levels of the maxima and a mean level, mean-min, of the measured levels of the minima; calculating the difference, mean-diff, between mean-max and mean-min; multiplying the mean difference, mean-diff, by a scaling factor of 0.55 and constraining it within lower and upper limits of 0.7 radians and 1.5 radians respectively to give a second margin; and subtracting the second margin from mean-max and mean-min respectively to give the first and second thresholds. At step S3, the detector 10 compares the measured signal levels of the turning points to current held-max and held-min values and discards levels of maxima that do not differ from the current held-min value by more than a first margin (of 0.7 radians) and levels of minima that do not differ from the current held-max by more than the first margin. At step S4, the detector 10 compares the measured signal levels of the turning points with the first and second thresholds and discards levels smaller than the thresholds. The detector 10 then outputs the measured signal levels of the remaining turning points as maximum and minimum levels of the signal, held-max and held-min, to the averaging means 11.

At step S5, the averaging means 11 calculates averages of adjacent maximum and minimum levels received from the detector 10 and outputs the calculated averages to the processing means 12. At step S6, the processing means 12 selects high, low and medium values of the calculated averages. At step S7, the processing means 12 calculates the DC offset value as the average of the selected high, low and medium values of the calculated averages. Such a DC offset value is largely independent of the content, e.g. bit values, of the signal.

In this embodiment, the DC offset value is estimated during an access code at the beginning of a data packet of the signal. The signal level ramps from zero to maximum at the start of transmission in just 2 μs. The preamble of the access code is 4 bits (or 4 μs) long. The next part of the access code is a sync word, which must be correctly received to allow the data packet to be correctly received. So, there is just 6 μs in which to estimate the DC offset value. Typically, the processing means 12 therefore selects the high, low and medium averages during just a period of just a few μs, say between 1 μs and 6 μs, as the set of averages on which to base the DC offset value.

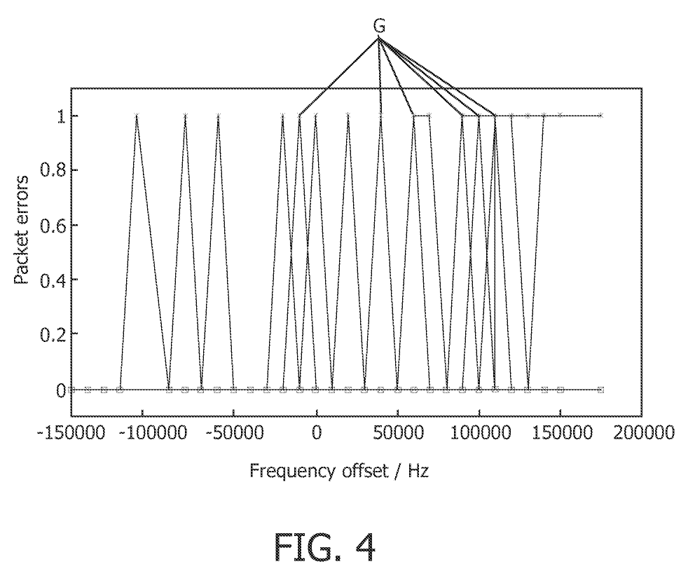

The DC offset estimation circuit 10 has been compared to the MaxMin technique of the prior art. A modelled GFSK modulated Bluetooth® signal was received with an actual DC offset between −150 KHz and +150 KHz and packet errors recorded. The results are plotted in FIG. 4. Each peak indicates a packet error, twelve of which were present when the MaxMin technique was used to set a DC offset value. However, when the DC offset estimation circuit 10 of the preferred embodiment of the invention was used, only six packet errors, indicated by the peaks labelled G, were present, indicating significantly improved performance.

Of course, the described embodiments of the invention are only examples of how the invention may be implemented. Other modifications, variations and changes to the described embodiments will occur to those having appropriate skills and knowledge. These modifications, variations and changes may be made without departure from the spirit and scope of the invention defined in the claims and its equivalents.

1. A DC offset estimation circuit, comprising:
a detector for repetitively detecting a maximum level and a minimum level of a signal;
averaging means for repetitively calculating an average of the detected maximum level and minimum level; and
processing means for selecting a set of the calculated averages and estimating a DC offset value based on the selected set of calculated averages.

2. The DC offset estimation circuit of claim 1, wherein the processing means sets the DC offset value as an average of the selected set of calculated averages.

3. The DC offset estimation circuit of claim 1, wherein the processing means selects the set of calculated averages by selecting averages in given ranges of values.

4. The DC offset estimation circuit of claim 1, wherein the processing means selects the set of calculated averages selected by selecting an average in a high range of values, an average in a low range of values and an average in a medium range of values.

5. The DC offset estimation circuit of claim 1, wherein the detector detects substantially every maximum level and every minimum level of at least a portion of the signal on which the DC offset correction is based.

6. The DC offset estimation circuit of claim 1, wherein the detector discards a maximum level of the signal that is less than a predetermined margin difference with a preceding minimum level of the signal.

7. The DC offset estimation circuit of claim 1, wherein the detector discards a minimum level of the signal that is less than a predetermined margin difference with a preceding maximum level of the signal.

8. The DC offset estimation circuit of claim 1, wherein the detector discards maximum and minimum levels of the signal that are smaller than respective first and second thresholds.

9. The DC offset estimation circuit of claim 8, wherein the detector calculates the first and second thresholds by subtracting a second margin from a mean of the detected maximum levels and a mean of the detected minimum levels of the signal respectively.

10. The DC offset estimation circuit of claim 9, wherein the detector calculates the second margin by scaling a difference between the mean of the detected maximum levels and the mean of the detected minimum levels.

11. The DC offset estimation circuit of claim 10, wherein the detector scales the difference by a scaling factor of approximately 0.55.

12. The DC offset estimation circuit of claim 9, wherein the detector constrains the second margin between upper and lower limits.

13. The DC offset estimation circuit of claim 1, adapted for use in a receiver.

14. The DC offset estimation circuit of claim 1, wherein the processing means calculates a mean of several of the detected maximum and minimum levels of the signal and estimates the DC offset value based on the calculated mean when the signal contains excessive noise.

15. The DC offset estimation circuit of claim 14, wherein the processing means determines that the signal contains excessive noise when the difference between the average of the selected set of calculated averages in a high range of values and the average of the selected set of calculated averages in a low range of values is greater than a predetermined value.

16. The DC offset estimation circuit of claim 14, wherein the processing means determines that the signal contains excessive noise when the calculated mean is higher than the average of the selected set of calculated averages in a high range of values or lower than the average of the selected set of calculated averages in a low range of values.

17. (canceled)

18. A method for estimating a DC offset value, comprising:
detecting a maximum level and minimum level of a signal;
calculating an average of the detected maximum level and minimum level;
repeating detecting and calculating to provide a plurality of averages;
selecting a set of the calculated averages; and
setting the DC offset value based on the selected set of averages.

19. (canceled)

20. A computer readable storage medium having a computer code embedded therein, the computer code, when carried out, estimating a DC offset value, comprising:
detecting a maximum level and minimum level of a signal;
calculating an average of the detected maximum level and minimum level;
repeating detecting and calculating to provide a plurality of averages;
selecting a set of the calculated averages; and
setting the DC offset value based on the selected set of averages.
